(19) United States
(12) Patent Application Publication
(10) Pub. No.: US 2026/0086456 A1
(43) Pub. Date: Mar. 26, 2026

(54) METHOD OF MANUFACTURING ORGANOMETALLIC OXIDE CLUSTER, PHOTORESIST COMPOSITION INCLUDING THE ORGANOMETALLIC OXIDE CLUSTER, AND METHOD OF MANUFACTURING SEMICONDUCTOR DEVICE USING THE PHOTORESIST COMPOSITION

(71) Applicant: Samsung Electronics Co., Ltd., Suwon-si (KR)

(72) Inventors: Yool Kang, Suwon-si (KR); Bongjin Moon, Seoul (KR); Ahram Suh, Suwon-si (KR); Woojung Kim, Seoul (KR); Taeyoon Park, Seoul (KR); Hanbee Kim, Suwon-si (KR); Kwanheum Lee, Suwon-si (KR)

(73) Assignees: SAMSUNG ELECTRONICS CO., LTD., Suwon-si (KR); SOGANG UNIVERSITY RESEARCH & BUSINESS DEVELOPMENT FOUNDATION, Seoul (KR)

(21) Appl. No.: 19/194,433

(22) Filed: Apr. 30, 2025

(30) Foreign Application Priority Data
Sep. 20, 2024 (KR) 10-2024-0127684

(51) Int. Cl. G03F 7/004; H01L 21/311; H01L 21/3213

(52) U.S. Cl. CPC G03F 7/0042; G03F 7/0048; H10P 50/71; H10P 50/73

(57) ABSTRACT

The inventive concept relates to a method of manufacturing an organometallic oxide cluster, a photoresist composition including the organometallic oxide cluster, and a method of manufacturing a semiconductor device using the photoresist composition, and more particularly, to a method of manufacturing an organometallic oxide cluster including a carbonyl group, a photoresist composition including the organometallic oxide cluster, and a method of manufacturing a semiconductor device using the photoresist composition.

### CROSS-REFERENCE TO RELATED APPLICATION

This application is based on and claims priority under 35 U.S.C. § 119 to Korean Patent Application No. 10-2024-0127684, filed on Sep. 20, 2024, in the Korean Intellectual Property Office, the disclosure of which is incorporated by reference herein in its entirety.

### FIELD OF THE INVENTION

The inventive concept relates to a method of manufacturing an organometallic oxide cluster, a photoresist composition comprising the organometallic oxide cluster, and a method of manufacturing a semiconductor device using the photoresist composition, and more particularly, to a method of manufacturing an organometallic oxide cluster comprising a carbonyl group, a photoresist composition comprising the organometallic oxide cluster, and a method of manufacturing a semiconductor device using the photoresist composition.

### BACKGROUND

As electronics technology advances, the down-scaling of integrated circuit components is rapid in progress. Accordingly, a photolithography process that is advantageous for implementing fine patterns is required. In particular, there is a need to develop materials capable of providing process stability, excellent etching resistance, and resolution in a photolithography process for manufacturing semiconductor devices.

### SUMMARY

The inventive concept provides a method of manufacturing an organometallic oxide cluster with improved photosensitivity, a photoresist composition comprising the organometallic oxide cluster, and a method of manufacturing a semiconductor device using the photoresist composition.

According to an aspect of the inventive concept, there is provided a photoresist composition including an organometallic oxide cluster comprising a ligand comprising a carbonyl group and a solvent.

According to another aspect of the inventive concept, there is provided a method of manufacturing an organometallic oxide cluster, the method comprising mixing a cluster precursor with an organic solvent and cooling the mixture of the cluster precursor and the organic solvent, adding a base dissolved in water to the cooled mixture of the cluster precursor and the organic solvent and stirring a resultant product while raising a temperature of the mixture, and extracting a water layer of the mixture and obtaining an organometallic oxide cluster from an organic layer of the mixture, wherein the organic solvent comprises an organic solvent that does not mix with the water.

According to another aspect of the inventive concept, there is provided a method of manufacturing a semiconductor device, the method comprising forming a feature layer on a substrate, forming a photoresist layer on the feature layer by using a photoresist composition comprising an organometallic oxide cluster comprising a ligand comprising a carbonyl group and a solvent, forming a cluster network from the organometallic oxide cluster in a first area, which is a portion of the photoresist layer, by exposing the first area, forming a photoresist pattern including the cluster network by developing the photoresist layer including the exposed first area, and etching the feature layer by using the photoresist pattern.

### BRIEF DESCRIPTION OF THE DRAWINGS

Embodiments will be more clearly understood from the following detailed description taken in conjunction with the accompanying drawings in which:

FIG. 1 illustrates a crosslinking mechanism of an organometallic oxide cluster according to embodiments;

FIG. 2 is a flowchart showing a method of manufacturing an organometallic oxide cluster, according to embodiments;

FIG. 3A illustrates a ¹H-nuclear magnetic resonance spectroscopy (NMR) spectrum of an organometallic oxide cluster according to embodiments;

FIG. 3B illustrates a ¹Sn-NMR spectrum of an organometallic oxide cluster according to embodiments;

FIG. 3C illustrates an electrospray ionization mass spectroscopy (ESI-MS) spectrum of an organometallic oxide cluster according to embodiments;

FIG. 3D illustrates a result of elemental analysis of organometallic oxide clusters according to embodiments;

FIG. 4A illustrates a ¹H-NMR spectrum of an organometallic oxide cluster according to other embodiments;

FIG. 4B illustrates a ¹Sn-NMR spectrum of an organometallic oxide cluster according to other embodiments;

FIG. 4C illustrates an ESI-MS spectrum of an organometallic oxide cluster according to other embodiments;

FIG. 4D illustrates a result of elemental analysis of an organometallic oxide cluster according to embodiments;

FIG. 5 illustrates a result of elemental analysis of an organometallic oxide cluster according to comparative examples;

FIG. 6 illustrates a ¹H-NMR spectrum of an organometallic oxide cluster according to other comparative examples;

FIG. 7 illustrates a ¹H-NMR spectrum of an organometallic oxide cluster according to other comparative examples;

FIG. 8 illustrates a change when extreme ultraviolet (EUV) light is irradiated onto an organometallic oxide cluster according to embodiments;

FIGS. 9A, 9B, and 10 are scanning electron microscope (SEM) images of photoresist patterns obtained from a photoresist composition including an organometallic oxide cluster according to embodiments;

FIG. 11 is a flowchart showing a method of manufacturing a semiconductor device using a photoresist composition including an organometallic oxide cluster, according to embodiments; and

FIGS. 12, 13, 14, 15, and 16 are cross-sectional views illustrating respective operations of a method of manufacturing a semiconductor device using a photoresist composition including an organometallic oxide cluster, according to embodiments.

### DETAILED DESCRIPTION OF THE EMBODIMENTS

Hereinafter, embodiments will be described in detail with reference to the accompanying drawings. The same elements in the drawings are denoted by the same reference numerals, and redundant descriptions thereof are omitted.

A photoresist composition according to embodiments may include an organometallic oxide cluster and a solvent, wherein the organometallic oxide cluster comprises a ligand comprising a carbonyl group.

In embodiments, the metal may be tin.

In embodiments, the organometallic oxide cluster may comprise a carbonyl group bonded to a beta position of a metal included in the organometallic oxide cluster.

In embodiments, the ligand may be an ester group.

In embodiments, the organometallic oxide cluster may comprise an organometallic oxide cluster represented by Formula 1:

[RSnO_{(3/2-x/2)}(OH)ₓ]ₙ [Formula 1]

In Formula 1, R is a C2-C30 functionalized hydrocarbyl group substituted with at least one heteroatom functional group selected from an oxygen atom, a nitrogen atom, a halogen element, cyano, thio, silyl, ether, carbonyl, ester, nitro, amino, or any combination thereof. The halogen element may be an F atom, a Cl atom, a Br atom, or an I atom. In addition, in Formula 1, x is an integer from 0 to 3 and n is an integer from 2 to 20.

In embodiments, the organometallic oxide cluster may have a football shape, a drum shape, a ladder shape, or a cage shape.

In embodiments, the organometallic oxide cluster may be included in an amount of about 1.5 wt % to about 10 wt % based on the total weight of the photoresist composition. For example, the organometallic oxide cluster may be included in an amount of about 1.5 wt % to about 5 wt % based on the total weight of the photoresist composition.

In the photoresist composition according to embodiments, the solvent may comprise an organic solvent. The organic solvent may be at least one of ether, alcohol, glycol ether, an aromatic hydrocarbon compound, ketone, or ester, but the inventive concept is not limited thereto. For example, the organic solvent may be ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbion: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or any combination thereof.

In the photoresist composition according to embodiments, the solvent may be included in a residual amount excluding the organometallic oxide cluster. In embodiments, the solvent may be included in an amount of about 0.1 wt % to about 99.8 wt % based on the total weight of the photoresist composition, but the inventive concept is not limited thereto.

In embodiments, the photoresist composition according to embodiments may further comprise at least one selected from a leveling agent, a surfactant, a dispersant, a moisture absorbent, and a coupling agent.

The leveling agent may improve coating flatness when coating the photoresist composition on a substrate. A known leveling agent that is commercially available may be used. When the photoresist composition includes comprises the leveling agent, the leveling agent may be included in an amount of about 0.001 wt % to about 3 wt % based on the total weight of the photoresist composition.

The surfactant may improve wettability and coating uniformity of the photoresist composition. In embodiments, the surfactant may be sulfate ester salt, sulfonate, phosphoric acid ester, soap, amine salt, quaternary ammonium salt, polyethylene glycol, alkylphenol ethylene oxide adduct, polyhydric alcohols, nitrogen-containing vinyl polymers, or any combination thereof, but the inventive concept is not limited thereto. For example, the surfactant may be an alkylbenzenesulfonate, alkylpyridinium salt, polyethylene glycol, or quaternary ammonium salt. When the photoresist composition comprises the surfactant, the surfactant may be included in an amount of about 0.001 wt % to about 3 wt % based on the total weight of the photoresist composition.

The dispersant may allow each component constituting the photoresist composition to be uniformly dispersed in the photoresist composition. In embodiments, the dispersant may be epoxy resin, polyvinyl alcohol, polyvinyl butyral, polyvinyl pyrrolidone, glucose, sodium dodecyl sulfate, sodium citrate, oleic acid, linoleic acid, or any combination thereof, but the inventive concept is not limited thereto. When the photoresist composition comprises the dispersant, the dispersant may be included in an amount of about 0.001 wt % to about 5 wt % based on the total weight of the photoresist composition.

The moisture absorbent may prevent the adverse effects caused by moisture in the photoresist composition. In embodiments, the moisture absorbent may be polyoxyethylene nonylphenolether, polyethylene glycol, polypropylene glycol, polyacrylamide, or any combination thereof, but the inventive concept is not limited thereto. When the photoresist composition comprises the moisture absorbent, the moisture absorbent may be included in an amount of about 0.001 wt % to about 10 wt % based on the total weight of the photoresist composition.

The coupling agent may improve adhesion with a lower layer when coating the photoresist composition on the lower layer. In embodiments, the coupling agent may be a silane coupling agent. The silane coupling agent may be vinyltrimethoxysilane, vinyltriethoxysilane, vinyltrichlorosilane, vinyltris (β-methoxyethoxy) silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy [3-(phenylamino) propyl]silane, but the inventive concept is not limited thereto. When the photoresist composition comprises the coupling agent, the coupling agent may be included in an amount of about 0.001 wt % to about 5 wt % based on the total weight of the photoresist composition.

In embodiments, the photoresist composition may be a photoresist composition for extreme ultraviolet (EUV) lithography.

The photoresist composition according to embodiments may include the organometallic oxide cluster. A carbonyl group, such as an ester group, may be bonded to a beta position of a metal included in the organometallic oxide cluster. An oxygen atom of the carbonyl group bonded to the beta position of the metal may be coordinated to the metal to weaken the bond between the metal and carbon of the carbonyl group. Accordingly, radicals may be easily formed from the organometallic oxide cluster, and thus, the photosensitivity of the organometallic oxide cluster may be improved. Therefore, a photoresist pattern having excellent contrast may be implemented even at a relatively low process temperature by using the photoresist composition including the organometallic oxide cluster.

In addition, since the carbonyl group is bonded to the organometallic oxide cluster, the solubility of the organometallic oxide cluster in the organic solvent included in the photoresist composition may be improved. Accordingly, since the photoresist composition does not need to include a separate additive for dissolving the organometallic oxide cluster, a cost reduction in a process of manufacturing a semiconductor device using the photoresist composition may be achieved.

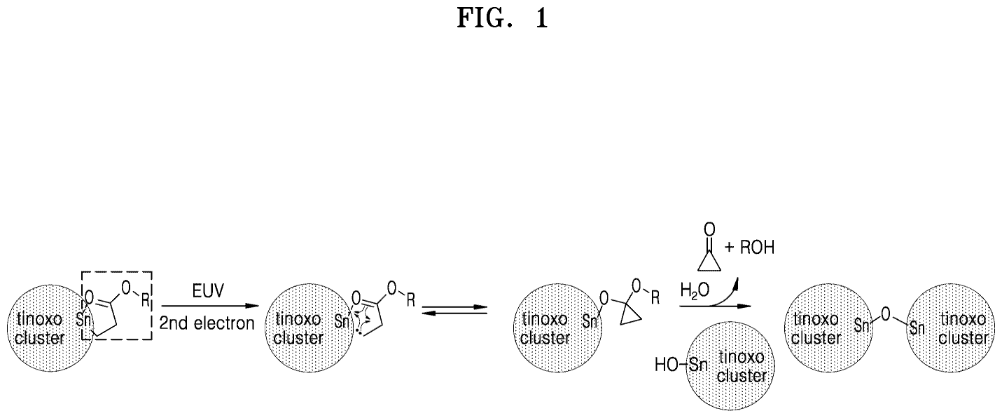

FIG. 1 illustrates a crosslinking mechanism of an organometallic oxide cluster according to embodiments.

Referring to FIG. 1, when the organometallic oxide cluster according to embodiments is irradiated with an active energy ray, for example, EUV light, ligands may be desorbed from the organometallic oxide cluster to form radicals. At this time, an oxygen atom of an ester group bonded to a metal of the organometallic oxide cluster according to embodiments may be coordinated to the metal to weaken the bond between the metal and carbon of the ester group. Accordingly, radicals may be easily formed even in an atmosphere without ambient oxygen.

Next, while a post exposure bake (PEB) process described below in a method of manufacturing a semiconductor device is performed, a condensation reaction of hydroxyl (—OH) functional groups of radicals formed by irradiation with an active energy ray may be induced. As a result, a network having a dense structure in which the organometallic oxide clusters are interconnected via oxygen atoms may be formed.

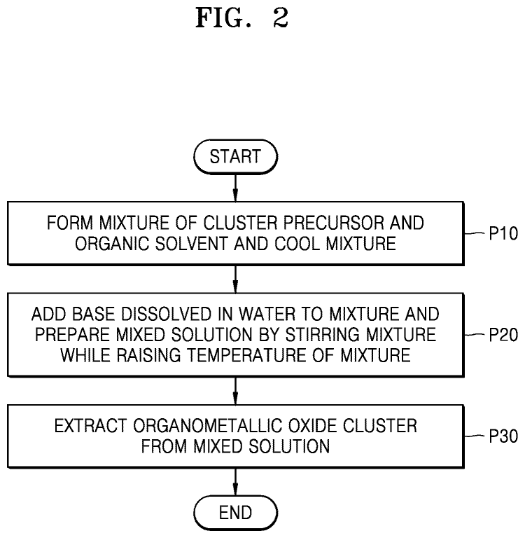

FIG. 2 is a flowchart showing a method of manufacturing an organometallic oxide cluster, according to embodiments.

Referring to FIG. 2, a cluster precursor and an organic solvent may be added to a flask to form a mixture of the cluster precursor and the organic solvent, and the mixture may be cooled by lowering the temperature of the mixture to about 0° C. (P10).

In embodiments, the cluster precursor may be a C2-C30 hydrocarbyl group substituted with at least one heteroatom functional group selected from an oxygen atom, a nitrogen atom, a halogen element, cyano, thio, silyl, ether, carbonyl, ester, nitro, amino, or any combination thereof. The halogen element may be, for example, an F atom, a Cl atom, a Br atom, or an I atom.

In embodiments, the organic solvent may be an organic solvent that is immiscible with water and forms a layer with water. The organic solvent may be, for example, tetrahydrofuran (THF), benzene, toluene, xylene, or any combination thereof.

Next, a base dissolved in water may be added to the mixture and a mixed solution may be prepared by stirring the mixture while raising the temperature of the mixture to which the base is added (P20). Through the stirring process, a reaction mixture of the cluster precursor and the base may be formed in the mixed solution. In the process P20, since a two-phase synthesis method using water and an organic solvent that does not mix with the water is used, an organic layer and a water layer may be formed in the mixed solution.

In embodiments, the base may be K₂CO₃, Na₂CO₃, KHCO₃, NaHCO₃, Cs₂CO₃, CsHCO₃, KOH, NaOH, CsOH, or any combination thereof.

In embodiments, the process P20 may be performed by using 3 equivalents of the base per 1 equivalent of the cluster precursor. Accordingly, since hydrolysis of the ester group included in the cluster precursor does not occur in the process P20, the organometallic oxide cluster according to the method of manufacturing an organometallic oxide cluster according to embodiments may include the ester group.

In embodiments, the ratio of the organic solvent to the water may be about 9:1 to about 1:9. For example, the ratio of the organic solvent to the water may be about 3:1.

In embodiments, the temperature of the mixture may be raised to about 25° C. to about 60° C. during the stirring process. For example, the temperature of the mixture may be raised to about 25° C.

In embodiments, the stirring process may be performed for about 1 hour to about 24 hours. For example, the stirring process may be performed for about 6 hours.

Next, the organometallic oxide cluster may be extracted from the mixed solution prepared through the process P20 (P30).

Specifically, in the process P30, the organic layer may be obtained from the reaction mixture of the mixed solution on which the process P20 is performed, and distilled water may be added to extract the water layer of the mixed solution. Next, the organometallic oxide cluster may be extracted by washing the organic layer and then drying and concentrating the washed organic layer.

In the method of manufacturing an organometallic oxide cluster, according to embodiments, the organometallic oxide cluster may be manufactured through the two-phase synthesis method using the water and the organic solvent that does not mix with the water. Therefore, the organometallic oxide cluster including the carbonyl group without metal contamination may be obtained in high yield through extraction alone without a separate purification process by the method of manufacturing an organometallic oxide cluster, according to embodiments.

Hereinafter, the organometallic oxide cluster according to the inventive concept is described in more detail through examples and comparative examples.

### Example 1

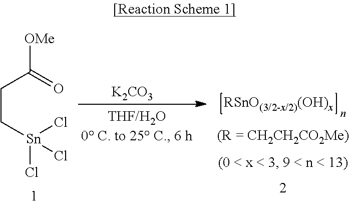

In Example 1, reactant 1, Cl₃SnCH₂CH₂CO₂Me (1.00 g, 3.20 mmol), was dissolved in 12 mL of THF in a 65-mL screw cap culture tube containing a stirring magnet and then cooled to 0° C. A solution in which potassium carbonate (0.66 g, 4.81 mmol) was dissolved in 4 mL of water was slowly added to the resultant product while stirring. Thereafter, the culture tube was closed with the screw cap and stirred at 25° C. for 6 hours. Thereafter, the reaction mixture was transferred to a separatory funnel, the organic layer in the separatory funnel was collected, 10 mL of distilled water was added to the separatory funnel, and the water layer was extracted three times with dichloromethane (15 mL×3 times). The collected organic layer was washed once with distilled water (20 mL), dried by adding sodium sulfate thereto, concentrated by using a vacuum rotary evaporator, and dried in vacuum to obtain product 2 in the form of a white solid (0.71 g, yield 91%).

### Example 2

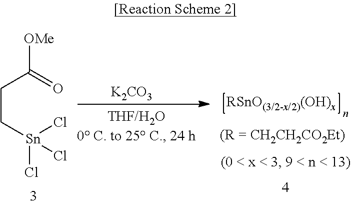

In Example 2, reactant 3, Cl₃SnCH₂CH₂CO₂Et (1.00 g, 3.07 mmol), was dissolved in 12 mL of THF in a 65-mL screw cap culture tube containing a stirring magnet and then cooled to 0° C. A solution in which potassium carbonate (0.64 g, 4.60 mmol) was dissolved in 4 mL of water was slowly added to the resultant product while stirring. Thereafter, the culture tube was closed with the screw cap and stirred at 25° C. for 24 hours. Thereafter, the reaction mixture was transferred to a separatory funnel, the organic layer in the separatory funnel was collected, 10 mL of distilled water was added to the separatory funnel, and the water layer was extracted three times with dichloromethane (15 mL×3 times). The collected organic layer was washed once with distilled water (20 mL), dried by adding sodium sulfate thereto, concentrated by using a vacuum rotary evaporator, and dried in vacuum to obtain product 4 in the form of a white solid (0.74 g, yield 97%).

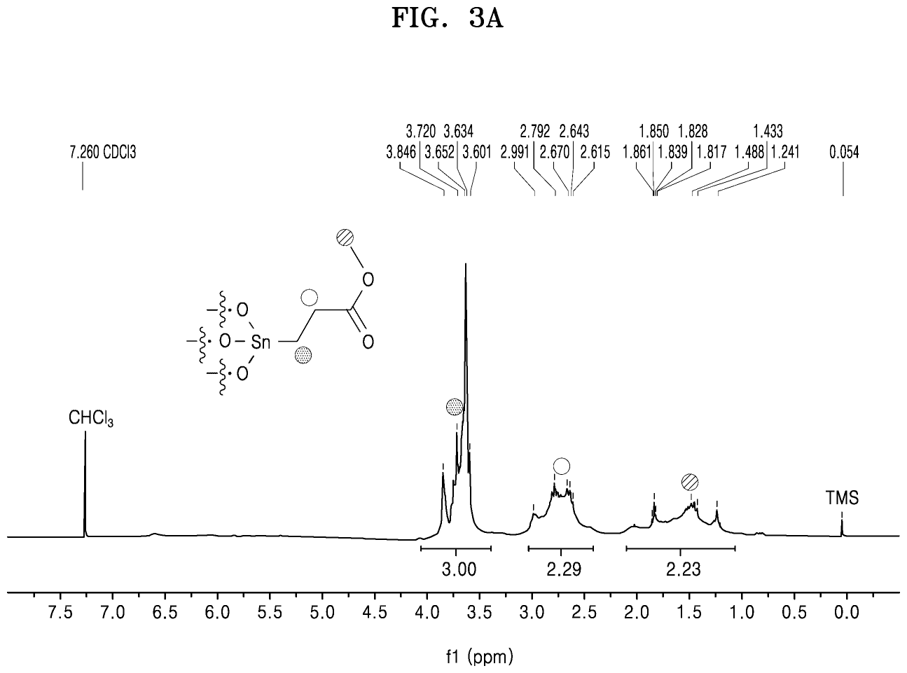

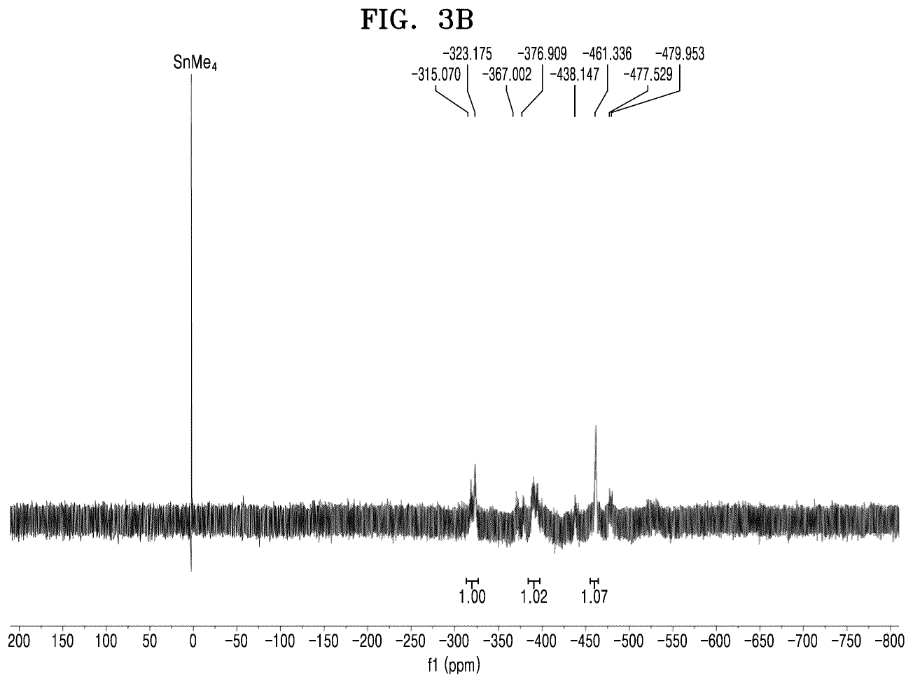

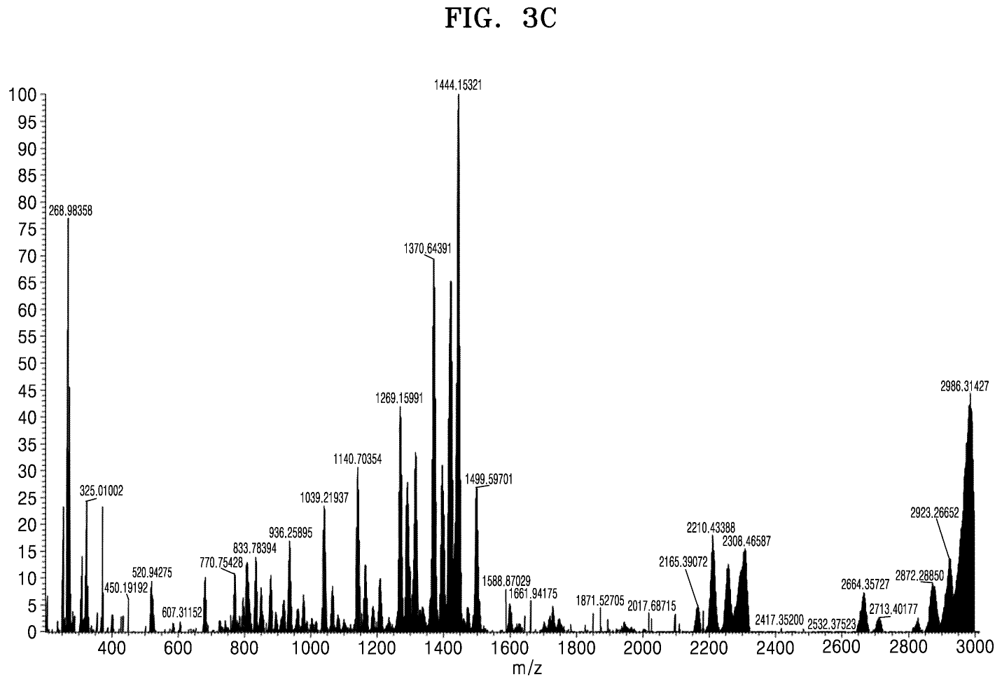

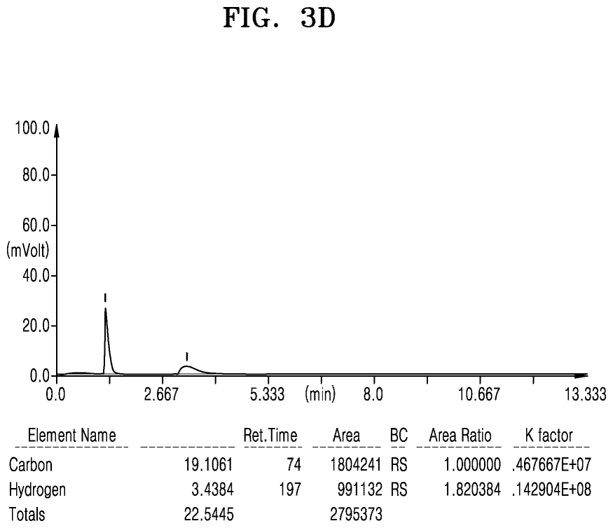

FIG. 3A illustrates a ¹H-nuclear magnetic resonance spectroscopy (NMR) spectrum of product 2 in Reaction Scheme 1. FIG. 3B illustrates a ¹Sn-NMR spectrum of product 2 in Reaction Scheme 1. FIG. 3C illustrates an electrospray ionization mass spectroscopy (ESI-MS) spectrum of product 2 in Reaction Scheme 1. FIG. 3D illustrates a result of elemental analysis of product 2 in Reaction Scheme 1.

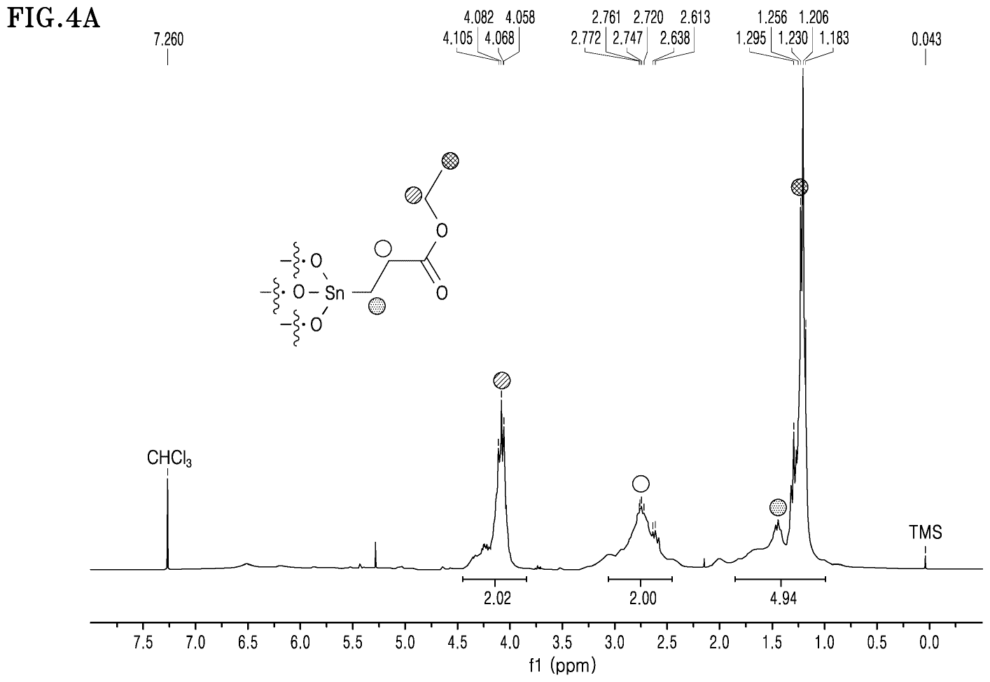

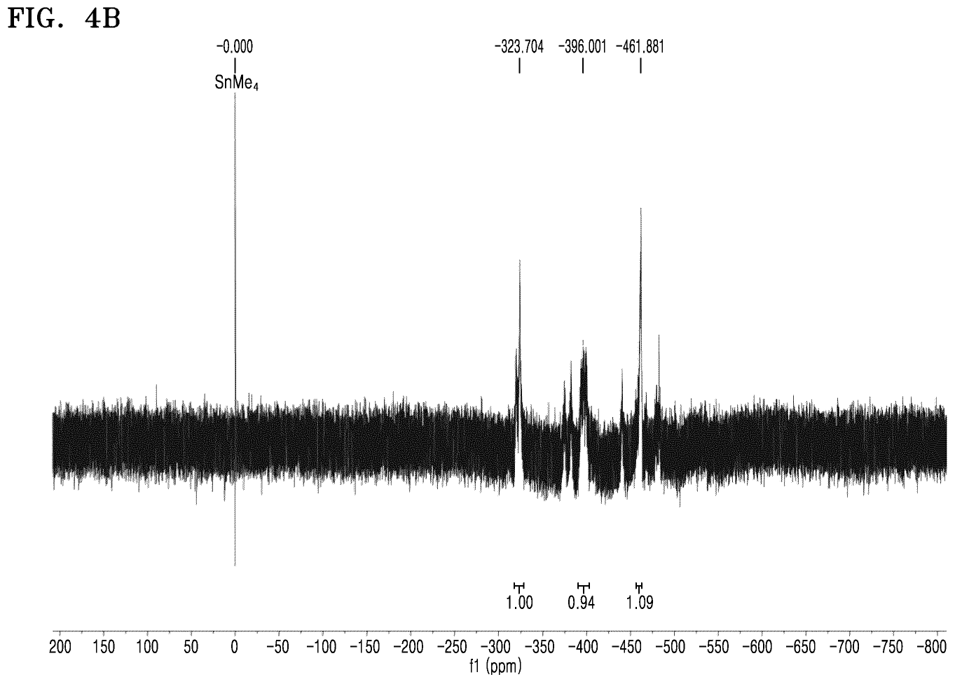

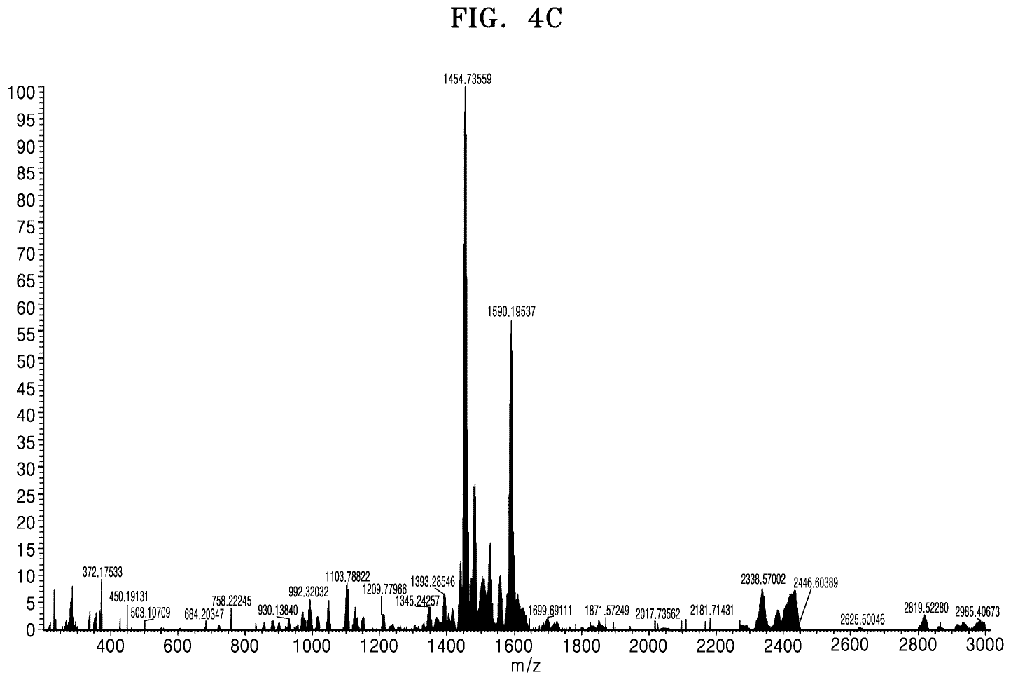

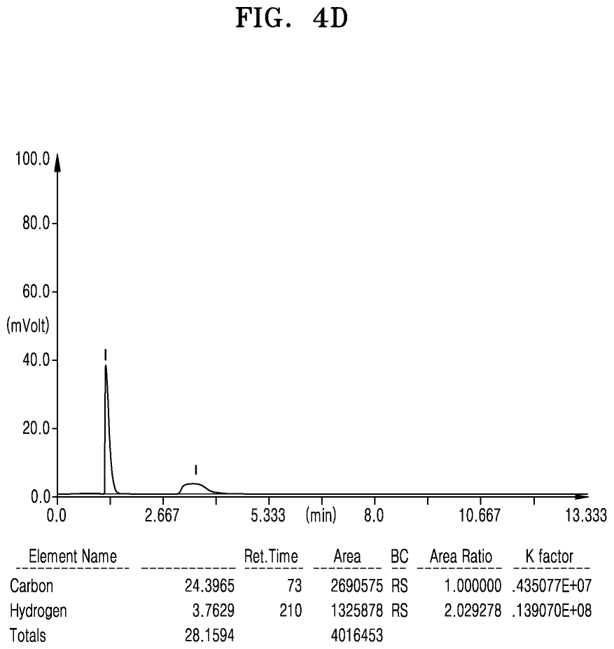

FIG. 4A illustrates a ¹H-NMR spectrum of product 4 in Reaction Scheme 2. FIG. 4B illustrates a ¹Sn-NMR spectrum of product 4 in Reaction Scheme 2. FIG. 4C illustrates an ESI-MS spectrum of product 4 in Reaction Scheme 2. FIG. 4D illustrates a result of elemental analysis of product 4 in Reaction Scheme 2.

In FIGS. 3A and 3B, the NMR spectrum analysis result of product 2 in Reaction Scheme 1 showed that a desired product was synthesized, and the presence of at least three tin (Sn) environments was confirmed through various types of ¹¹⁹Sn resonance.

In FIGS. 4A and 4B, the NMR spectrum analysis result of product 4 in Reaction Scheme 2 showed that a desired product was synthesized, and the presence of at least three tin (Sn) environments was confirmed through various types of ¹¹⁹Sn resonance.

In the ESI-MS spectrum of product 2 in Reaction Scheme 1 of FIG. 3C, a peak is observed at m/z=1370 (divalent cation), and in the ESI-MS spectrum of product 4 in Reaction Scheme 2 of FIG. 4C, a peak is observed at m/z=1454 (divalent cation). Since the difference in m/z value between the peak of product 2 in Reaction Scheme 1 and the peak of product 4 in Reaction Scheme 2 is 84, it may be confirmed that the difference in molecular weight between product 2 in Reaction Scheme 1 and product 4 in Reaction Scheme 2 is 168 g/mol. Since the difference in molecular weight is equal to the difference in molecular weight between product 2 in Reaction Scheme 1 and product 4 in Reaction Scheme 2, i.e., a value obtained by multiplying the difference in molecular weight between the cluster precursor in Reaction Scheme 1 and the cluster precursor in Reaction Scheme 2 by 12, it may be confirmed that the cluster precursor in Reaction Scheme 1 and the cluster precursor in Reaction Scheme 2 each contain 12 Sn atoms. In addition, the difference in m/z value between the peaks of m/z=833.78, m/z=936.26, and m/z=1039.22 in FIG. 3C indicates an increase in the number of precursors constituting the cluster in Reaction Scheme 1, and the difference in m/z value between the peaks of m/z=1454.74 and m/z=1590.20 in FIG. 4C indicates an increase in the number of precursors constituting the cluster in Reaction Scheme 2.

Referring to the elemental analysis result of FIGS. 3D and 4D, it may be confirmed that the composition ratio calculated from Reaction Scheme 1 and the composition ratio calculated from Reaction Scheme 2 coincide with each other.

### Comparative Example 1

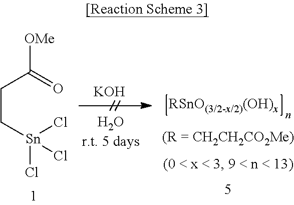

In Comparative Example 1, reactant 1, Cl₃SnCH₂CH₂CO₂Me (0.18 g, 0.57 mmol), and 100 μL of water were added to a 10-mL round-bottom flask containing a stirring magnet and stirred at room temperature. 1 M potassium hydroxide solution (0.11 g, 2.0 mL, 2.0 mmol) was slowly added to the resultant product for 2 hours. After confirming that the pH of the mixture was 4.0, the mixture was stirred for 5 days. Thereafter, the generated white precipitate was filtered out and washed with 20 mL of distilled water. After washing the white precipitate, the white precipitate was dried in the air to obtain product 5 in the form of a white solid (0.012 g, yield 9%).

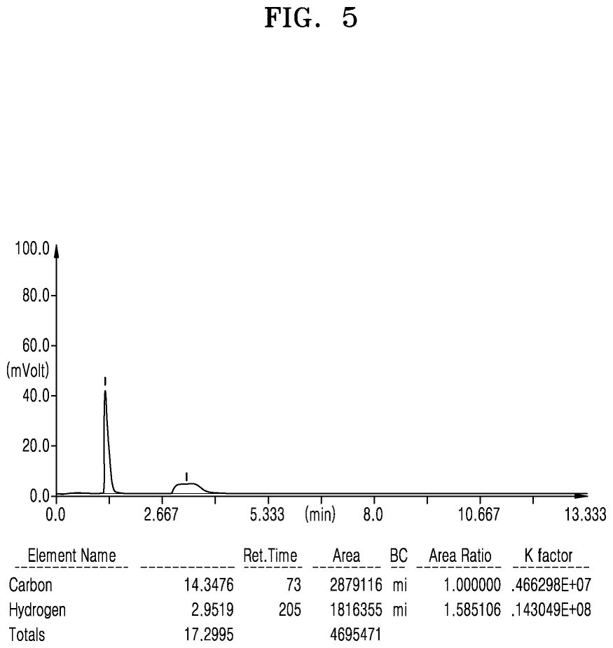

FIG. 5 illustrates a result of elemental analysis of product 5 in Reaction Scheme 3.

Referring to FIG. 5, the theoretical calculation values calculated from Reaction Scheme 3 are 19.99% C and 3.21% H, but the elemental analysis result of FIG. 5 shows 14.35% C and 2.95% H. Accordingly, it may be confirmed that a desired high-purity organometallic oxide cluster was not synthesized from Comparative Example 1.

### Comparative Example 2

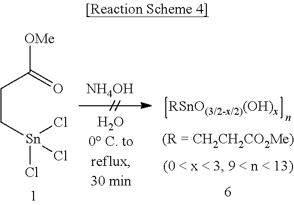

In Comparative Example 2, 5 mL of water was added to a 65-mL screw cap culture tube containing a stirring magnet, and nitrogen gas was bubbled for 10 minutes to create a nitrogen atmosphere. Next, the culture tube was cooled to 0° C. and 28 wt % ammonia water (1.2 g, 9.6 mmol) was added thereto in a nitrogen atmosphere. Next, the solution in the culture tube was stirred and reactant 1, Cl₃SnCH₂CH₂CO₂Me (1.00 g, 3.20 mmol), was rapidly added thereto. Thereafter, the culture tube was closed with the screw cap and the reaction mixture was stirred and refluxed for 30 minutes. After the culture tube was cooled to room temperature, a column chromatography tube was filled with celite and the reaction mixture was passed therethrough to remove impurities. After the celite was washed twice with THE, a filtrate was extracted three times with dichloromethane (30 mL×3 times). An organic layer extracted therefrom was collected, dried by adding sodium sulfate, concentrated by using a vacuum rotary evaporator, and dried in vacuum to obtain product 6 in the form of a white solid (23 mg, yield 3%).

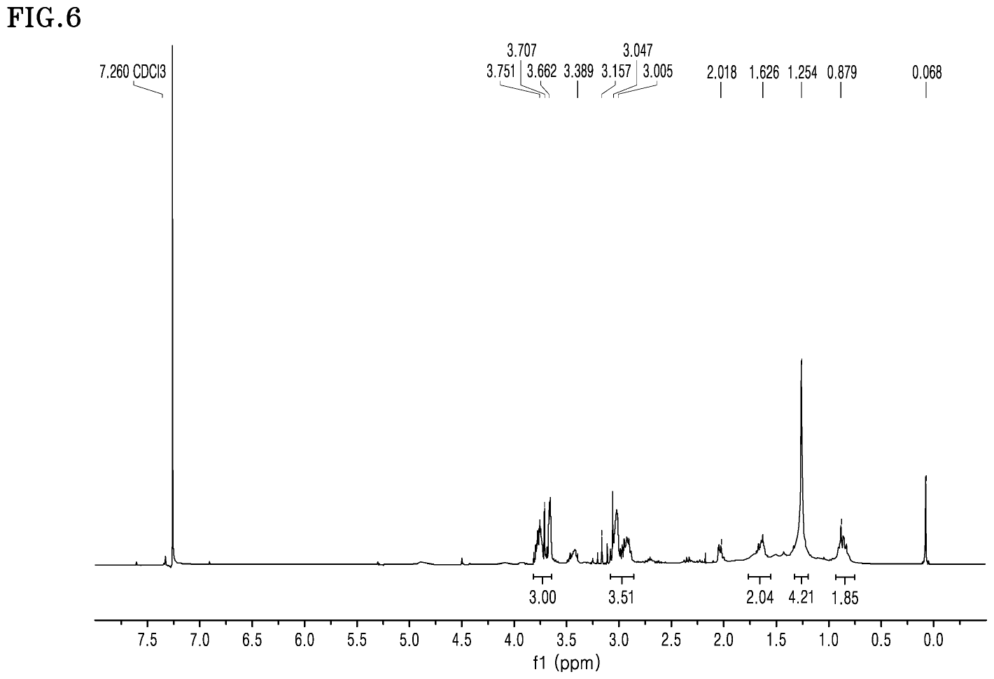

FIG. 6 illustrates a ¹H-NMR spectrum of product 6 in Reaction Scheme 4.

Referring to FIG. 6, when comparing the NMR spectrum of product 6 obtained through Reaction Scheme 4 with the NMR spectrum of FIG. 3A, it may be confirmed that the spectrum of product 6 obtained through Reaction Scheme 4 is different from the spectrum of product 2 obtained through Reaction Scheme 1. That is, it may be confirmed that a desired high-purity organometallic oxide cluster was not synthesized from Comparative Example 2.

### Comparative Example 3

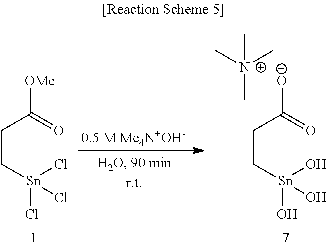

In Comparative Example 3, reactant 1, Cl₃SnCH₂CH₂CO₂Me (1.00 g, 3.20 mmol), was added to 32 mL of a 0.50 M tetramethylammonium hydroxide aqueous solution and stirred vigorously at room temperature for 90 minutes. During the stirring process, no white precipitate that was insoluble in water was precipitated. After the stirring process, 5.0 mL of the reaction solution was taken and freeze-dried to obtain product 7 in the form of a white solid (0.34 g, yield 44%).

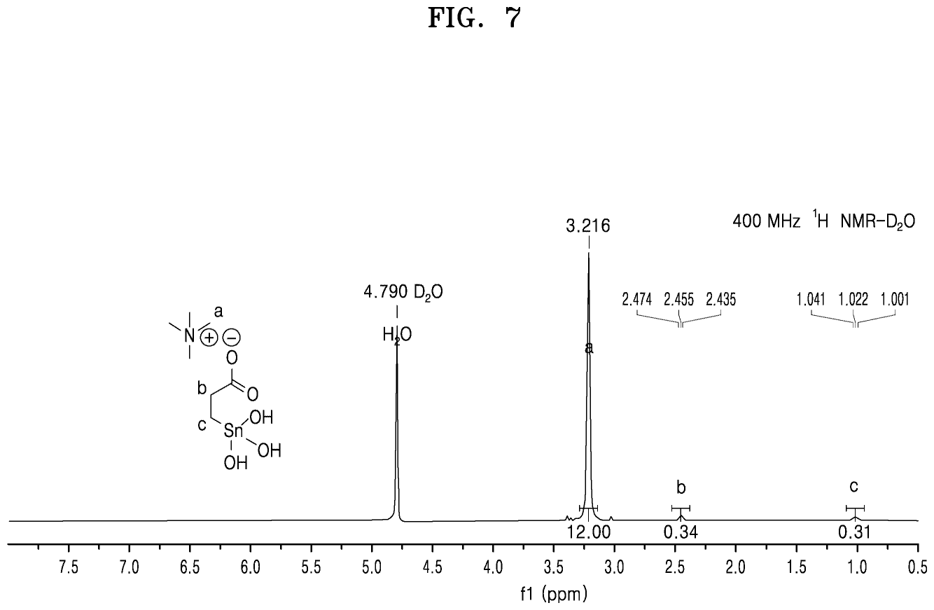

FIG. 7 illustrates a ¹H-NMR spectrum of product 7 in Reaction Scheme 5.

In Reaction Scheme 5, since the reaction was carried out by adding 5 equivalents of tetramethylammonium hydroxide and 1 equivalent of reactant 1 in Reaction Scheme 5, the theoretical integral ratio of the hydrolyzed product 7 is a:b:c=12:0.4:0.4.

Referring to the NMR spectrum of product 7 in FIG. 7, it may be confirmed that the actual integral ratio in the NMR spectrum of FIG. 7 is similar thereto. In addition, it may be confirmed that no peak indicating a methyl ester group is observed in the NMR spectrum of FIG. 7. That is, it may be confirmed that, when reactant 1 reacts in accordance with Reaction Scheme 5, an organometallic oxide cluster having a ligand including an ester group is not obtained.

Hereinafter, characteristics of product 2 obtained through Example 1 and product 4 obtained through Example 2 are described in more detail.

### Evaluation Example 1

### Evaluation of Solubility

Products 2 and 4 synthesized in Examples 1 and 2 were respectively dissolved in propylene glycol monomethyl ether (PGME) and propylene glycol monomethyl ether acetate (PGMEA) and the solubility thereof was measured by identifying the weight up to the point of maximum solubility. As a result, it was confirmed that product 2 comprising a methyl ester group had a solubility of 20 wt % or more in PGME, and product 4 comprising an ethyl ester group had a solubility of 20 wt % or more in both PGME and PGMEA.

### Evaluation Example 2

Products 2 and 4 synthesized in Examples 1 and 2 were each dissolved in acetonitrile (ACN) and added to a cuvette, and then, products 2 and 4 synthesized in Examples 1 and 2 were each exposed to UV light.

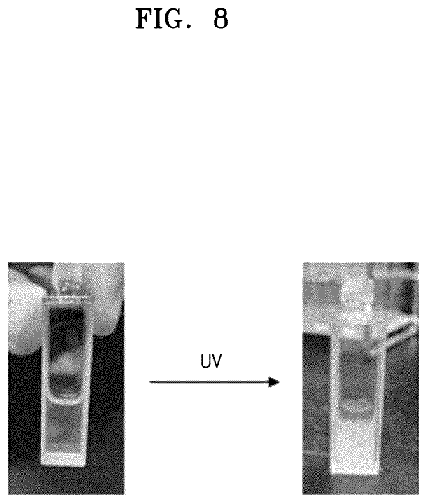

FIG. 8 illustrates a change when EUV light is irradiated onto an organometallic oxide cluster according to embodiments. Referring to FIG. 8, it was confirmed that, when products 2 and 4 synthesized in Examples 1 and 2 were each exposed to EUV light, white precipitates were formed, as illustrated in FIG. 8.

### Formation of Photoresist Pattern

3 wt % of product 2 synthesized in Example 1 was dissolved in PGME and then spin-coated on a wafer. Thereafter, a soft bake process was performed thereon at 80° C. for 1 minute, an exposure process was performed by using an electron beam (E-beam) to form a line-and-space pattern, and then, a post-bake process was performed thereon at 120° C. for 1 minute. Thereafter, the obtained resultant product was immersed in PGMEA and developed for 30 seconds to form photoresist patterns including a line-and-space pattern.

3 wt % of product 4 synthesized in Example 2 was dissolved in PGMEA and then spin-coated on a wafer. Thereafter, a soft bake process was performed thereon at 80° C. for 1 minute, an exposure process was performed by using an E-beam to form a line-and-space pattern, and then, a post-bake process was performed thereon at 120° C. for 1 minute. Thereafter, the obtained resultant product was immersed in PGMEA and developed for 30 seconds to form photoresist patterns including a line-and-space pattern.

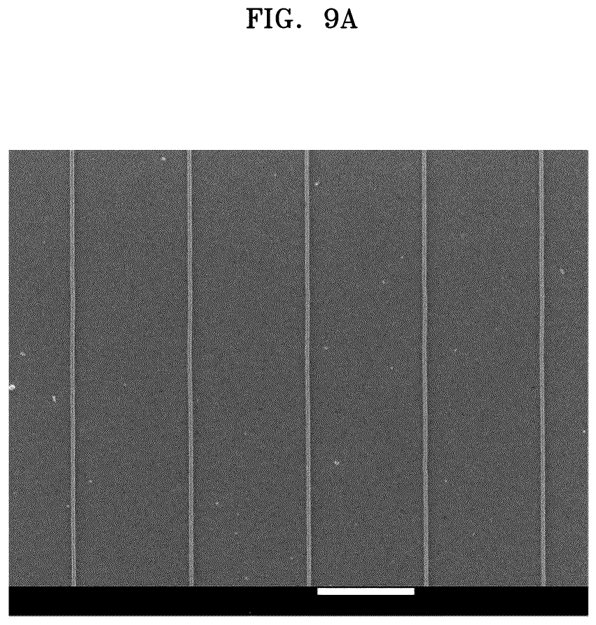

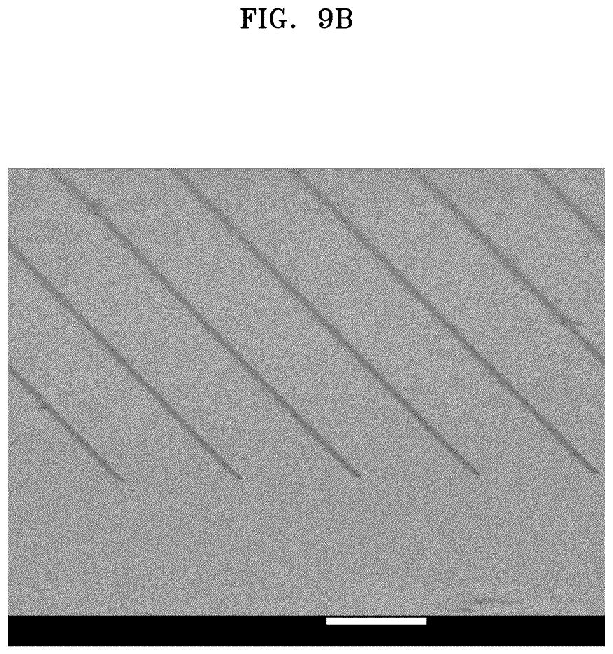

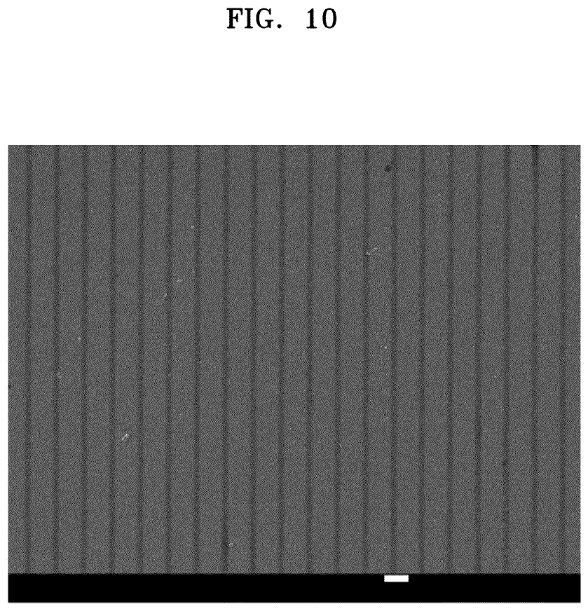

FIGS. 9A, 9B, and 10 are scanning electron microscope (SEM) images of photoresist patterns obtained from a photoresist composition including an organometallic oxide cluster according to embodiments. Specifically, FIGS. 9A and 9B are SEM images of the photoresist pattern obtained from the photoresist composition comprising product 2 synthesized in Example 1, and FIG. 10 is an SEM image of the photoresist pattern obtained from the photoresist composition comprising product 4 synthesized in Example 2.

Referring to FIGS. 9A and 9B, when a photoresist layer was formed through a photolithography process using the photoresist composition comprising product 2 synthesized in Example 1, it may be confirmed that a photoresist pattern having a line width of about 33 nm was satisfactorily formed.

Referring to FIG. 10, when a photoresist layer was formed through a photolithography process using the photoresist composition comprising product 4 synthesized in Example 2, it may be confirmed that a photoresist pattern having a line width of about 258 nm was satisfactorily formed.

That is, referring to FIGS. 9A, 9B, and 10, it may be confirmed that, even when either PGME or PGMEA is used alone as a developer, the photoresist composition comprising the organometallic oxide cluster according to the embodiments has excellent solubility in the developer.

In addition, in the photolithography process using the photoresist composition comprising the organometallic oxide cluster according to the embodiments, it may be confirmed that a photoresist pattern is well implemented even when a soft bake process and a post-bake process are performed at a relatively low process temperature, compared to a general photolithography process.

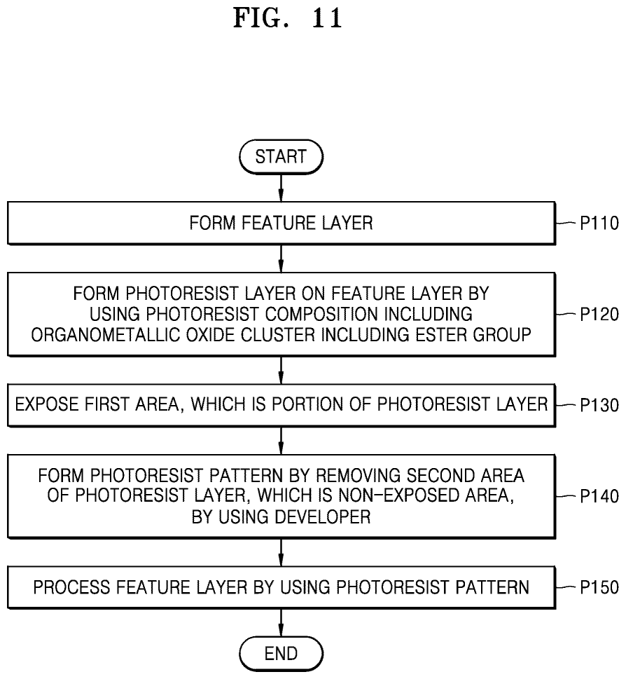

FIG. 11 is a flowchart showing a method of manufacturing a semiconductor device using a photoresist composition comprising an organometallic oxide cluster, according to embodiments.

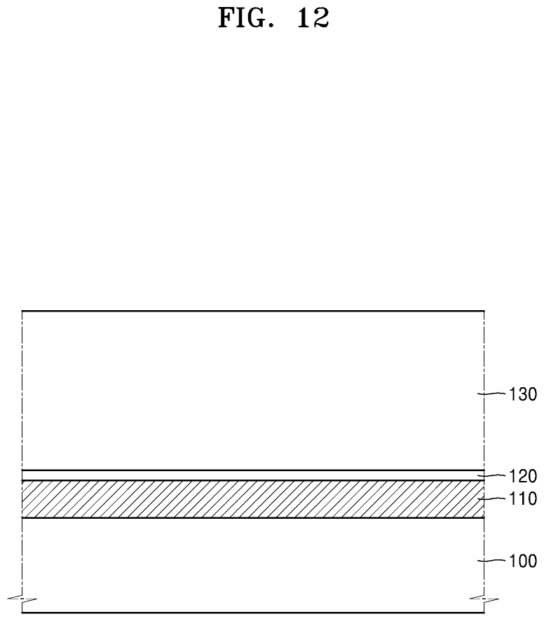

FIGS. 12, 13, 14, 15, and 16 are cross-sectional views illustrating respective operations of a method of manufacturing a semiconductor device using a photoresist composition comprising an organometallic oxide cluster, according to embodiments.

Referring to FIGS. 11 and 12, a feature layer 110 may be formed on a substrate 100 (P110). Thereafter, a resist lower layer 120 may be formed on the feature layer 110. Next, a photoresist layer 130 may be formed on the feature layer 110 and the resist lower layer 120 by using a photoresist composition according to embodiments (P120). Details of the photoresist composition are the same as described above.

The substrate 100 may be an area where a semiconductor device including various types of individual devices is formed. The individual devices may include various microelectronic devices, for example, a metal-oxide-semiconductor field effect transistor (MOSFET) such as a complementary metal-insulator-semiconductor transistor (CMOS transistor), system large scale integration (LSI), an image sensor such as a CMOS imaging sensor (CIS), a micro-electro-mechanical system (MEMS), an active element, or a passive element. In embodiments, the substrate 100 may include a semiconductor die area for forming a memory semiconductor chip or a logic circuit chip. For example, the semiconductor die area may be an area for forming a volatile memory semiconductor chip, such as dynamic random access memory (DRAM) or static random access memory (SRAM), or a non-volatile memory semiconductor chip, such as phase-change random access memory (PRAM), magnetoresistive random access memory (MRAM), ferroelectric random access memory (FeRAM), or resistive random access memory (RRAM).

The feature layer 110 may include a material necessary to constitute elements to be formed in the semiconductor die area. In embodiments, the feature layer 110 may include an insulating layer or a conductive layer. For example, the feature layer 110 may include metal, alloy, metal carbide, metal nitride, metal oxynitride, metal oxycarbide, semiconductor, polysilicon, oxide, nitride, oxynitride, or any combination thereof, but the inventive concept is not limited thereto.

The resist lower layer 120 may be arranged between the feature layer 110 and the photoresist layer 130 and may prevent problems caused when the irradiated radiation reflected from below the photoresist layer 130 is scattered into the photoresist layer 130.

In embodiments, the resist lower layer 120 may include a developable bottom anti-reflective coating (DBARC) layer. The DBARC layer may control diffuse reflection of light from a light source used in an exposure process or may absorb reflected light from the feature layer 110 therebelow. In embodiments, the DBARC layer may include an organic anti-reflective coating (ARC) material for a light source, such as a KrF excimer laser, an ArF excimer laser, an F2 excimer laser, or an EUV laser. In embodiments, the DBARC layer may include an organic component having a light-absorbing structure. The light-absorbing structure may be, for example, a hydrocarbon compound having at least one benzene ring or a structure in which benzene rings are fused.

In other embodiments, the resist lower layer 120 may include a carbon-containing layer. For example, the resist lower layer 120 may include a carbon layer, a doped carbon layer, or an amorphous carbon layer (ACL). The doped carbon layer may include a dopant including O, Si, N, W, B, I, Cl, or any combination thereof.

The resist lower layer 120 may have a thickness of about 1 nm to about 100 nm. A plasma-enhanced chemical vapor deposition (PECVD) or an atomic layer deposition (ALD) process may be used to form the resist lower layer 120, but the inventive concept is not limited thereto. In embodiments, the resist lower layer 120 may be omitted.

To form the photoresist layer 130, a photoresist composition according to embodiments may be coated on the resist lower layer 120. The coating may be performed by spin coating, spray coating, or dip coating. A process of heat-treating the photoresist composition may be performed at a temperature of about 80° C. to about 300° C. for about 10 seconds to about 100 seconds, but the inventive concept is not limited thereto. The thickness of the photoresist layer 130 may be several tens to several hundred times the thickness of the resist lower layer 120. The photoresist layer 130 may be formed to a thickness of about 10 nm to about 1 μm, but the inventive concept is not limited thereto.

After the photoresist layer 130 is formed, a soft bake process may be performed on the photoresist layer 130. The soft bake process may be performed on the photoresist layer 130 at a temperature of about 50° C. to about 100° C. for about 10 seconds to about 100 seconds. While the soft bake process is performed on the photoresist layer 130, a solvent in the photoresist layer 130 may evaporate and adhesion between the photoresist layer 130 and the resist lower layer 120 may increase.

Since the organometallic oxide cluster according to embodiments comprises an ester group, the organometallic oxide may have improved photosensitivity. Therefore, the soft bake process on the photoresist layer 130 comprising the photoresist composition comprising the organometallic oxide cluster according to embodiments may be performed at a relatively low temperature.

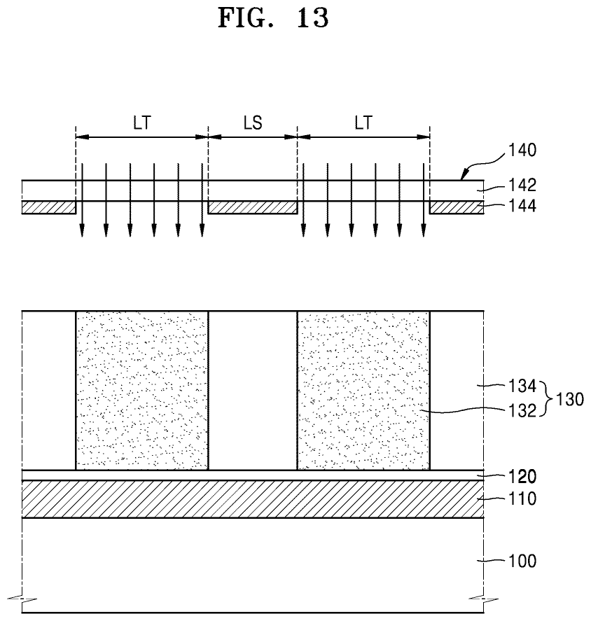

Referring to FIGS. 11 and 13, a first area 132, which is a portion of the photoresist layer 130, may be exposed and a PEB process may be performed by applying heat to the photoresist layer 130 including the exposed first area 132 so that a cluster network may be formed from the organometallic oxide cluster included in the photoresist layer 130 in the first area 132 (P130).

In embodiments, in order to expose the first area 132 of the photoresist layer 130, a photomask 140 having a plurality of light-shielding areas LS and a plurality of light-transmitting areas LT may be aligned at a certain position with the photoresist layer 130 and the first area 132 of the photoresist layer 130 may be exposed through the plurality of light-transmitting areas LT of the photomask 140. In order to expose the first area 132 of the photoresist layer 130, a KrF excimer laser (248 nm), an ArF excimer laser (193 nm), an F2 excimer laser (157 nm), or an EUV laser (13.5 nm) may be used.

In embodiments, the photomask 140 may include a transparent substrate 142 and a plurality of light-shielding patterns 144 formed in the plurality of light-shielding areas LS above the transparent substrate 142. The transparent substrate 142 may include quartz. The plurality of light-shielding patterns 144 may include chromium (Cr). The plurality of light-transmitting areas LT may be defined by the plurality of light-shielding patterns 144. According to the inventive concept, a reflective photomask (not shown) for EUV exposure may be used instead of the photomask 140 so as to expose the first area 132 of the photoresist layer 130.

The PEB process may be performed at a temperature of about 50° C. to about 140° C. for about 10 seconds to about 150 seconds. For example, the PEB process may be performed at a temperature of about 120° C. to about 140° C. for about 60 seconds to about 120 seconds, but the inventive concept is not limited thereto.

Since the organometallic oxide cluster according to embodiments comprises an ester group, the organometallic oxide may have improved photosensitivity. Therefore, the post-bake process on the photoresist layer 130 comprising the photoresist composition comprising the organometallic oxide cluster according to embodiments may be performed at a relatively low temperature.

When the first area of the photoresist layer 130 is exposed, the first area 132 of the photoresist layer 130 may absorb an active energy ray, for example, EUV light so that organic ligands may be desorbed from the organometallic oxide cluster included in the photoresist layer 130, and thus, radicals may be formed. Thereafter, during the PEB process, a condensation reaction of hydroxyl (—OH) functional groups may be induced in the first area 132. As a result, dense cluster networks interconnected via oxygen atoms may be formed.

In a second area 134, which is a non-exposed area of the photoresist layer 130, cluster networks are not formed, and the organometallic oxide cluster included in the photoresist layer 130 may maintain the original state thereof without structural change. Accordingly, the difference in solubility in the developer between the first area 132 and the second area 134 of the photoresist layer 130 may increase.

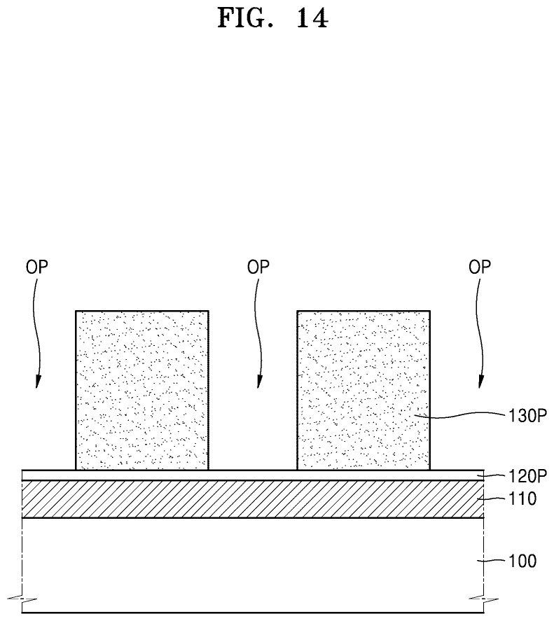

Referring to FIGS. 11 and 14, the second area 134 of the photoresist layer 130 may be removed by developing the photoresist layer 130 using the developer (P140). As a result, a photoresist pattern 130P including the cluster network formed in the exposed first area 132 of the photoresist layer 130 may be formed.

A plurality of openings OP may be defined by the photoresist pattern 130P. In a plan view, each of the plurality of openings OP may have a line shape or a hole shape. After the photoresist pattern 130P is formed, a lower pattern 120P may be formed by removing portions of the resist lower layer 120 exposed through the plurality of openings OP.

In embodiments, the development of the photoresist layer 130 may be performed by a negative-tone development (NTD) process. In embodiments, a developer including an organic solvent may be used to develop the photoresist layer 130. Examples of the developer may include PGMEA, PGME, MIBC, methyl ethyl ketone, acetone, cyclohexanone, 2-heptanone, 4-methyl-2-propanol, 1-butanol, isopropanol, 1-propanol, methanol, ethyl acetate, ethyl lactate, n-butyl acetate, butyrolactone, benzene, xylene, toluene, or any combination thereof, but the inventive concept is not limited thereto.

Since the organometallic oxide cluster according to embodiments comprises the ester group, the photoresist layer 130 (see FIG. 13) comprising the photoresist composition comprising the organometallic oxide cluster may have excellent solubility in the organic solvent. Therefore, in the process of developing the photoresist layer 130 (see FIG. 13), the photoresist layer 130 (see FIG. 13) may be developed by using only the organic solvent without the need to use a separate additive such as acetic acid.

In embodiments, after the photoresist pattern 130P is formed by developing the photoresist layer 130 as described with reference to FIG. 14, a hard bake process may be further performed on the obtained resulting structure. The hard bake process may remove unnecessary materials such as the developer remaining on the resulting structure on which the photoresist pattern 130P has been formed. The hard bake process may be performed at a temperature of about 50° C. to about 400° C. for about 10 seconds to about 150 seconds. For example, the hard bake process may be performed at a temperature of about 150° C. to about 250° C. for about 60 seconds to about 120 seconds, but the inventive concept is not limited thereto.

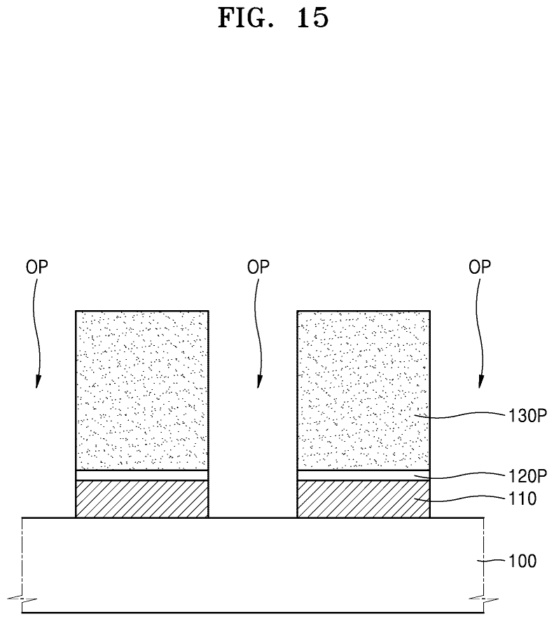

Referring to FIGS. 11 and 15, the photoresist pattern 130P may be used as an etch mask in the resulting structure of FIG. 14 to etch some areas of the feature layer 110 through the plurality of openings OP to form a feature pattern 110P (P150).

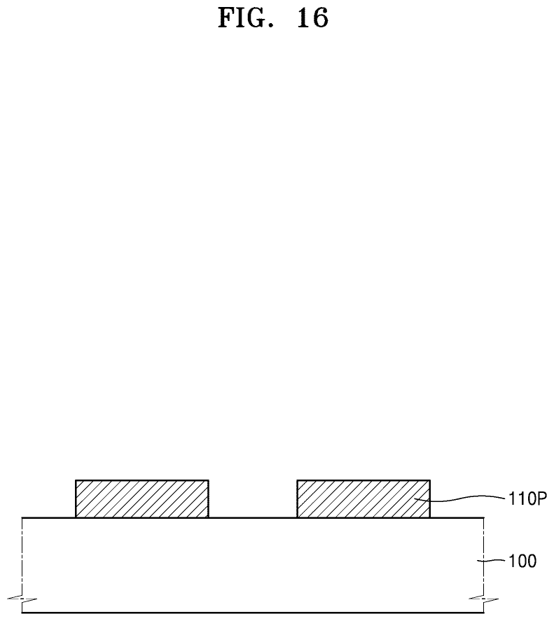

Referring to FIG. 16, the photoresist pattern 130P and the resist lower layer 120 remaining on the feature pattern 110P may be removed.

According to the method of manufacturing a semiconductor device, according to embodiments, described with reference to FIGS. 11 and 12 to 16, since the photoresist layer is formed by using the photoresist composition according to embodiments, the photoresist pattern having excellent contrast may be formed even when the soft bake process and the post-bake process are performed at a relatively low temperature. In addition, since the development process may be performed by using only the organic solvent without any separate additives, a cost reduction in the semiconductor device manufacturing process may be improved.

While the inventive concept has been particularly shown and described with reference to embodiments thereof, it will be understood that various changes in form and details may be made therein without departing from the spirit and scope of the following claims.

What is claimed is:

1. A photoresist composition comprising:
an organometallic oxide cluster comprising a ligand comprising a carbonyl group; and
a solvent.

2. The photoresist composition of claim 1, wherein the ligand is bonded to a beta position of a metal included in the organometallic oxide cluster.

3. The photoresist composition of claim 1, wherein the organometallic oxide cluster is represented by Formula 1: 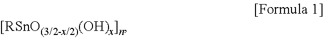
wherein, R comprises a C2-C30 hydrocarbyl group substituted with at least one heteroatom functional group selected from an oxygen atom, a nitrogen atom, a halogen element, cyano, thio, silyl, ether, carbonyl, ester, nitro, amino, or any combination thereof, the halogen element comprises an F atom, a Cl atom, a Br atom, or an I atom, x is an integer from 0 to 3 and n is an integer from 2 to 20.

4. The photoresist composition of claim 1, wherein the ligand comprises an ester group.

5. The photoresist composition of claim 1, wherein the organometallic oxide cluster has a football shape, a drum shape, a ladder shape, or a cage shape.

6. The photoresist composition of claim 1, wherein the organometallic oxide cluster is included in an amount of about 1.5 wt % to about 10 wt % based on a total weight of the photoresist composition.

7. The photoresist composition of claim 1, wherein the solvent comprises propylene glycol methyl ether, propylene glycol methyl acetate, 4-methyl-2-pentanol (methyl isobutyl carbion: MIBC), or any combination thereof.

8. The photoresist composition of claim 1, wherein the solvent does not comprise an acid.

9. A method of manufacturing an organometallic oxide cluster, the method comprising:
mixing a cluster precursor with an organic solvent and cooling a mixture of the cluster precursor and the organic solvent;
adding a base dissolved in water to the cooled mixture of the cluster precursor and the organic solvent and stirring a resultant product while raising a temperature of the mixture; and
extracting a water layer of the mixture and obtaining an organometallic oxide cluster from an organic layer of the mixture,
wherein the organic solvent comprises an organic solvent that does not mix with the water.

10. The method of claim 9, wherein the organic solvent comprises tetrahydrofuran (THF), benzene, toluene, xylene, or any combination thereof.

11. The method of claim 9, wherein the cluster precursor comprises a C2-C30 hydrocarbyl group substituted with at least one heteroatom functional group selected from an oxygen atom, a nitrogen atom, a halogen element, cyano, thio, silyl, ether, carbonyl, ester, nitro, amino, or any combination thereof, and the halogen element comprises an F atom, a Cl atom, a Br atom, or an I atom.

12. The method of claim 9, wherein the base comprises K₂CO₃, Na₂CO₃, KHCO₃, NaHCO₃, Cs₂CO₃, CsHCO₃, KOH, NaOH, CsOH, or any combination thereof.

13. The method of claim 9, wherein the stirring comprises stirring the mixture while raising the temperature of the mixture to about 25° C. to about 60° C.

14. The method of claim 9, wherein the stirring is performed for about 1 hour to about 24 hours.

15. A method of manufacturing a semiconductor device, the method comprising:
forming a feature layer on a substrate;
forming a photoresist layer on the feature layer by using a photoresist composition comprising an organometallic oxide cluster comprising a ligand comprising a carbonyl group and a solvent;
forming a cluster network from the organometallic oxide cluster in a first area, which is a portion of the photoresist layer, by exposing the first area;
forming a photoresist pattern comprising the cluster network by developing the photoresist layer comprising the exposed first area; and
etching the feature layer by using the photoresist pattern.

16. The method of claim 15, wherein the ligand comprises an ester group and the ligand is bonded to a beta position of a metal included in the organometallic oxide cluster.

17. The method of claim 15, wherein the organometallic oxide cluster is represented by Formula 1: 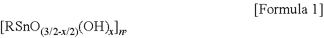
wherein, R comprises a C2-C30 hydrocarbyl group substituted with at least one heteroatom functional group selected from an oxygen atom, a nitrogen atom, a halogen element, cyano, thio, silyl, ether, carbonyl, ester, nitro, amino, or any combination thereof, the halogen element comprises an F atom, a Cl atom, a Br atom, or an I atom, x is an integer from 0 to 3 and n is an integer from 2 to 20.

18. The method of claim 15, wherein the organometallic oxide cluster has a football shape, a drum shape, a ladder shape, or a cage shape.

19. The method of claim 15, wherein the organometallic oxide cluster is included in an amount of about 1.5 wt % to about 10 wt % based on a total weight of the photoresist composition.

20. The method of claim 15, wherein the solvent comprises propylene glycol methyl ether, propylene glycol methyl acetate, 4-methyl-2-pentanol (methyl isobutyl carbion: MIBC), or any combination thereof.
